(19) United States
(12) Patent Application Publication
(10) Pub. No.: US 2010/0244064 A1
(43) Pub. Date: Sep. 30, 2010

(54) LIGHT SOURCE

(75) Inventors: Chan Bit Tie, Bayan Lepas (MY); Siang Ling Oon, Bukit Mertajam (MY); Ng Kee Yean, Prai (MY)

Correspondence Address: Kathy Manke;Avago Technologies Limited, 4380 Ziegler Road, Fort Collins, CO, 80525, US

(73) Assignee: Avago Technologies ECBU IP (Singapore) Pte. Ltd., Sigapore (SG)

(21) Appl. No.: 12/413,475

(22) Filed: Mar. 27, 2009

(51) Int. Cl. H01L 33/00

(52) U.S. Cl. 257/98; 257/E33.055

(57) ABSTRACT

A light source is described herein. An embodiment of the light source comprises a reflector cup having a cavity; a light emitter located in the cavity; a first encapsulant encompassing the light emitter; and a film located adjacent the first encapsulant, the film comprising phosphor.

### BACKGROUND

Some light sources have a light emitter that emits a narrow bandwidth of light. In order to change the perceived color of light emitted by the light sources, phosphor is placed in an encapsulant that encompasses the light emitter. The phosphor may settle, which causes an inconsistent light emission. In addition, the phosphor may not be evenly distributed within the encapsulant, which will cause an inconsistent light emission.

### BRIEF DESCRIPTION OF THE DRAWINGS

FIG. 1 is a side cut away view of an embodiment of an light source.

FIG. 2 is another embodiment of the light source of FIG. 1 wherein the light source has angled reflector cup walls.

FIG. 3 is a side cutaway view of another embodiment of a light source.

### DETAILED DESCRIPTION

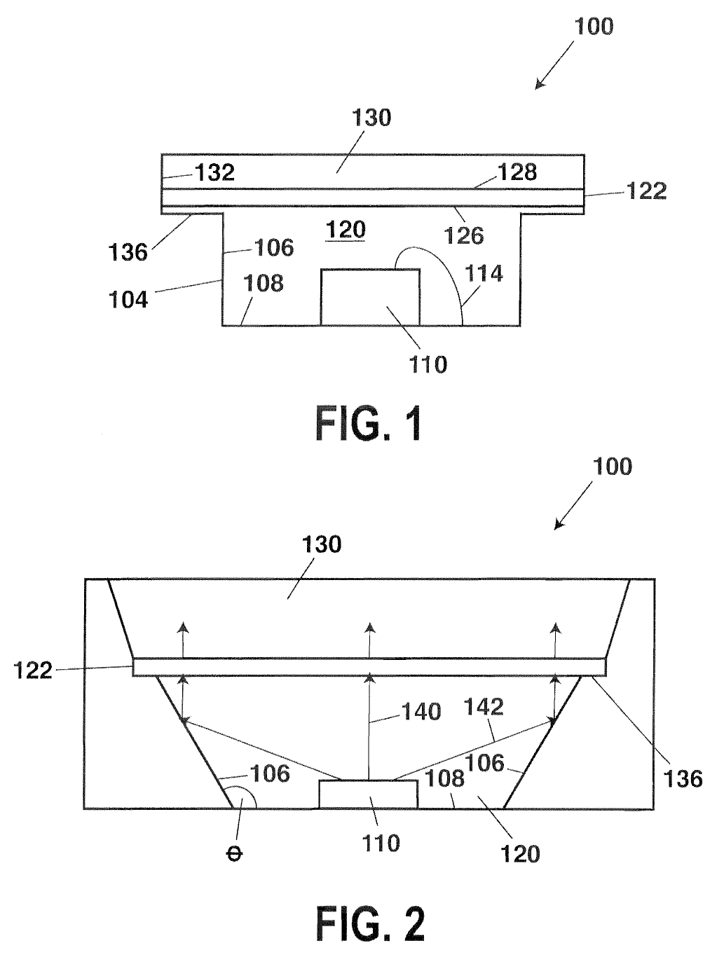

An embodiment of a light source 100 is shown FIG. 1, which is a side cut away view of a light source 100. The light source 100 includes a cup 104, which is sometimes referred to as a reflector cup 104. The cup 104 may have an interior surface 106 that reflects light as described in greater detail below. The interior surface 106 may be shaped so as to reflect light depending on design criteria. Another embodiment of a cup is shown in FIG. 2 and is described in greater detail below. The cup 104 may also have a bottom surface 108 to which a light emitter 110 is attached. In some embodiments, the light emitter 110 is a light-emitting diode (LED).

The bottom surface 108 may have a plurality of electrical traces and the like (not shown in FIG. 1) that are used to conduct electricity to the light emitter 110. The light emitter 110 may connect to a trace by way of its placement on a trace. For example, the light emitter 110 may have a terminal located on its lower side that sets on and conducts with a trace. In the embodiment of FIG. 1, a single electrical contact may be made between a trace and the light source 110. The second electrical contact may be made by way of a wire 114 that connects the light emitter 110 to the trace.

A first space 120 or cavity exists between the interior surface 106, the bottom surface 108 and a film 122, which is discussed in greater detail below. The space 120 is filled with an encapsulant. In some embodiments, the space 120 is filled with a clear encapsulant. A clear encapsulant is a material that does not significantly react with the light emitted by the light emitter 110 so as to change the perceived color of light emitted by the light source 100 from that emitted by the light emitter 110. In some embodiments, the encapsulant is silicone or its primary component is silicone.

The encapsulant serves to protect the components of the light source 100 from contaminants and moisture. For example, the encapsulant keeps contaminants and moisture from deteriorating the traces, the light emitter 110, and the wire 114.

Conventional light sources use an encapsulant in the space 120 that has phosphor or the like within the encapsulant. The phosphor serves to change the perceived color of light emitted by the light source 100 from that emitted by the light emitter 110. One problem with having phosphor within the encapsulant is that it is difficult to get the phosphor evenly distributed throughout the phosphor. The result is nonuniform color emission from the light source. Another problem is that the phosphor can settle within the encapsulant, which reduces the effect of the phosphor. Yet another problem with conventional light sources is that heat causes the phosphor to lose its conversion efficiency. Therefore, when phosphor is located in the encapsulant, it can be close to the light emitter 110, which may cause the phosphor to lose its efficiency.

In order to overcome the problems described above, the phosphor or other light changing substance is located within the film 122. The film 122 has a first side 126 and a second side 128, wherein the first side 126 is located adjacent or faces the space 120. Thus, the film 122 is adjacent or in contact with the encapsulant. Phosphor granules or other light converting substances are located between the first side 126 and the second side 128 of the film. Therefore, light emitted by the light source 110 is incident with the first side 126 of the film 122. As the light passes through the film 122, some of the light contacts the phosphor and is converted to another wavelength of light. The light emitted at the second side 128 of the film 122 is perceived to be a different color than the light emitted by the light emitter 110. More specifically, the light emitted by the light source may have the original wavelength emitted by the light emitter 110 in addition to wavelengths changed by the phosphor.

The phosphor or other substances are located in the film 122. Therefore, the phosphor will not settle and can be evenly distributed within the film. The result is that the light emitted by the light source 110 is very consistent. Another benefit of the film 122 is that the phosphor cannot settle. Therefore, the light emitted by the light emitter 110 will always contact phosphor and will be converted to another color based on the amount of phosphor in the film 122. The film 122 provides a further benefit in that the color conversion can be checked prior to assembly of the light source 100. For example, light can be shined through the film 122 and the resulting light color can be checked. This is not possible with conventional light sources wherein the phosphor is located within the encapsulant.

In some embodiments, such as the embodiment of FIG. 1, the light source may have a second encapsulant located in a second space 130. The light source 100 may have an upper wall 132 wherein the upper wall and the second side 128 of the film 122 form the second space 130. The second encapsulant serves to keep moisture and contaminants from contacting the film 122. The encapsulants in the space 120 and the second space 130 may be the same material. Thus, their coefficients of thermal expansion may be the same, so they expand and contract the same when heated and cooled. This reduces the chance of either encapsulant delaminating from the reflector cup 104 or the wall 132.

In some embodiments, the second encapsulant is harder than the first encapsulant and may form a lens. The film 122 may be attached to the second encapsulant before assembly into the reflector cup 104. For example, if the second encapsulant is a lens, the film 122 may be attached to the lens, then the lens may be placed into the reflector cup 104.

In some embodiments, the reflector cup 104 has a ledge 136. In the embodiment of FIG. 1, the ledge 136 is covered by the encapsulant. In other embodiments, the second first side 126 of the film 122 may be placed against the ledge 136. The placement of the film 122 on the ledge 136 may enhance the adhesion of the film 122 within the reflector cup 104.

One of the benefits of the film 122 is shown in FIG. 2, which is an embodiment of the light source 100 wherein the interior surface 106 of the reflector cup is tapered. More specifically, an angle θ exists between the interior surface 106 and the bottom surface 108 and the angle θ is greater than ninety degrees. In this situation, there are several different length light paths passing through the space 120 and the encapsulant. Reference is made to a first light path 140 and a second light path 142 wherein the first light path 140 is longer than the second light path 142. In conventional light sources that have the phosphor in the encapsulant, the longer light paths may intersect more phosphor than shorter light paths. Thus, in a conventional light source, the longer light path 142 may intersect more phosphor than the shorter light path 140. The result is that the light emitted by the light source may not be consistent.

The light source 100 described herein overcomes this problem by use of the film 122. The thickness of the film 122 may be consistent and the density of phosphor or the like in the film 122 may also be consistent. Therefore, light emitted along the first light path 140 will be the same wavelength as light emitted along the second light path 142 because the only change in wavelength occurs in the film 122.

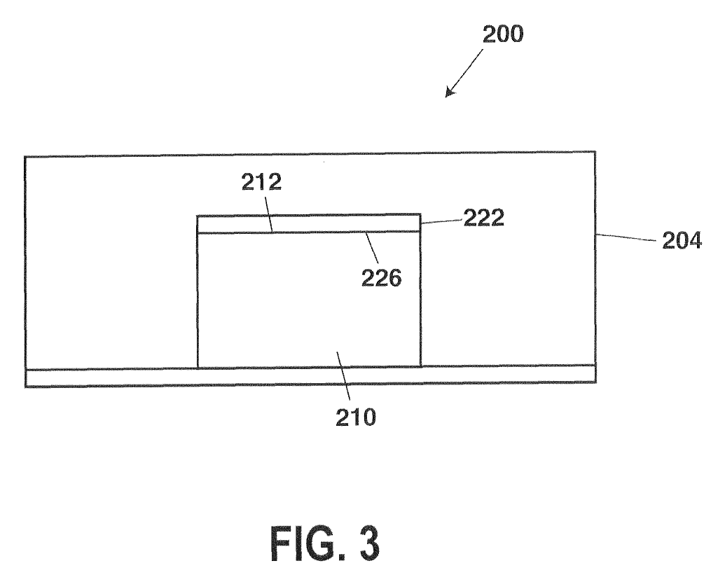

Another embodiment of a light source 200 using a film is shown in FIG. 3. The light source 200 has a reflector cup 204 that may be virtually any shape. The shape of the reflector cup 204 of FIG. 3 is substantially rectangular. A light emitter 210 is located within the reflector cup 204 in a conventional manner. The light emitter 210 has an emitter surface 212 wherein light is emitted from the emitter surface 212. In this embodiment, the film 222 is attached to the emitter surface 212 of the light source 210.

The reflector cup 204 may be filled with an encapsulant to the extent that the encapsulant covers the film 222. The encapsulant serves to keep contaminants from interfering or degrading the components within the light source 200.

In the embodiment of FIG. 3, the film 222 may be attached to the light source 210 prior to the light source 210 being mounted in the reflector cup. In some embodiments, this may reduce the production time and costs. With regard to operation, the light source 200 still emits a consistent wavelength of light because all the light passes through the film 222.

What is claimed is:

1. A light source comprising:
a reflector cup having a cavity;
a light emitter located in said cavity;
a first encapsulant encompassing said light emitter; and
a film located adjacent said first encapsulant, said film comprising phosphor.

2. The light source of claim 1 wherein said film has a first side and a second side opposite said first side; wherein said first side is located adjacent said first encapsulant; and further comprising a second encapsulant located adjacent said second side of said film.

3. The light source of claim 2, wherein said first encapsulant and said second encapsulant are made of the same material.

4. The light source of claim 2, wherein the coefficient of thermal expansion of said first encapsulant is substantially the same as the coefficient of thermal expansion of said second encapsulant.

5. The light source of claim 1, wherein said reflector cup has walls and wherein said walls are reflective to light emitted by said light emitter.

6. The light source of claim 1, wherein said first encapsulant comprises silicone.

7. The light source of claim 1, wherein said first encapsulant comprises clear silicone.

8. The light source of claim 1, wherein said light emitter is a light-emitting diode.

9. The light source of claim 1, wherein said reflector cup comprises a ledge and wherein at least a portion of said film is located proximate said ledge.

10. The light source of claim 9, wherein at least a portion of said film contacts said ledge. 136

11. The light source of claim 1, wherein said reflector cup comprises an interior surface and a bottom surface, said light emitter being located on said bottom surface, and wherein said interior surface and said bottom surface intersect at an angle that is greater than ninety degrees.

12. The light source of claim 1, wherein said second encapsulant is harder than said first encapsulant.

13. The light source of claim 1, wherein said second encapsulant forms a lens.

14. A light source comprising:
a reflector cup comprising a cavity;
a light emitter located in said cavity, said light emitter comprising a light emitting surface; and
a film located adjacent said light emitting surface, said film comprising phosphor.

15. The light source of claim 14, wherein said film is adhered to said light emitting surface.

16. The light source of claim 14, wherein said film is in contact with said light emitting surface.

17. The light source of claim 14 and further comprising an encapsulant in said cavity, said encapsulant being in contact with said film.

18. The light source of claim 17, wherein said encapsulant comprises silicone.

19. The light source of claim 17, wherein said encapsulant comprises clear silicone.

20. The light source of claim 14, wherein said reflector cup comprises an interior surface and a bottom surface, said light emitter being located on said bottom surface, and wherein said interior surface and said bottom surface intersect at an angle that is greater than ninety degrees.
